(19) United States
(12) Patent Application Publication
(10) Pub. No.: US 2014/0043014 A1
(43) Pub. Date: Feb. 13, 2014

(54) PHASE-LOCKED LOOP

(71) Applicant: ABB Technology AG, Zurich (CH)

(72) Inventors: Ngai-Man HO, Fislisbach (CH); Gerardo ESCOBAR, Merida (MX); Sami PETTERSSON, Wettingen (CH)

(73) Assignee: ABB Technology AG, Zurich (CH)

(21) Appl. No.: 13/964,369

(22) Filed: Aug. 12, 2013

(30) Foreign Application Priority Data
Aug. 13, 2012 (EP) 12180224.3

(51) Int. Cl. G01R 25/00; H03L 7/08

(52) U.S. Cl. CPC G01R 25/00; H03L 7/08
USPC 324/76.19; 327/156

(57) ABSTRACT

A phase-locked loop and method for estimating a phase angle of a three-phase reference signal is disclosed, which includes an adaptive quadrature signal generator configured to calculate an estimated first state and an estimated second state of a model of an unbalanced three-phase system at a fundamental frequency of the reference signal on a basis of the reference signal and an estimated fundamental frequency; a reference frame transformation block configured to calculate a direct component and a quadrature component in a rotating reference frame synchronous with an estimated phase angle on a basis of the fundamental positive sequence component and the estimated phase angle, and configured to determine an estimate of an amplitude of the fundamental positive sequence component on the basis of the direct component; and an estimator configured to determine estimates of the estimated fundamental frequency and the estimated phase angle on the basis of the quadrature component.

### RELATED APPLICATION(S)

This application claims priority under 35 U.S.C. §119 to European Application No. 12180224.3 filed in Europe on Aug. 13, 2012, the entire content of which is hereby incorporated by reference in its entirety.

### FIELD

The present disclosure relates to synchronization with a three-phase reference signal, for example, in situations where the reference signal is unbalanced and/or subject to harmonic distortion.

### BACKGROUND INFORMATION

In some applications, it can be desirable to be able to synchronize with a reference signal. For example, in distributed power generation, grid connected power converters can be synchronized with the phase and frequency of a utility grid.

A phase-locked loop (PLL) can be used for synchronizing with a signal. PLLs can be formed in various ways. For example, a synchronous reference frame phase-locked loop (SRF-PLL) is a PLL technique which is capable of detecting a phase angle and a frequency of a reference signal.

Different designs have been proposed based on the SRF-PLL approach. As many other designs, the SRF-PLL is based on a linearization assumption, for example, the results can be guaranteed locally. The SRF-PLL can yield a fast and precise detection of the phase angle, fundamental frequency and amplitude of the reference signal.

However, designs based on the SRF-PLL approach can be prone to fail due to harmonic distortion. The bandwidth of the SRF-PLL feedback loop can be reduced to reject and cancel out the effect of these harmonics on the output, if the reference signal is distorted with low-order harmonics, for example, harmonics close to the fundamental frequency. In some cases, however, reducing the PLL bandwidth can be an unacceptable solution as the speed of response of the PLL can be considerably reduced as well.

Further, unbalance in the reference signal can cause issues for designs based on the SRF-PLL approach.

### SUMMARY

A phase-locked loop for estimating a phase angle of a three-phase reference signal is disclosed, wherein the phase-locked loop comprises: an adaptive quadrature signal generator configured to calculate an estimated first state and an estimated second state of a model of an unbalanced three-phase system at a fundamental frequency of the reference signal on a basis of the reference signal and an estimated fundamental frequency, wherein the model includes a first state representing a sum of a positive and a negative sequence component of the reference signal at a harmonic frequency, and a second state representing a difference between the positive sequence component and the negative sequence component; a positive sequence generator configured to calculate a fundamental positive sequence component of the reference signal on a basis of the estimated first state and the estimated second state; a reference frame transformation block configured to calculate a direct component and a quadrature component in a rotating reference frame synchronous with an estimated phase angle on a basis of the fundamental positive sequence component and the estimated phase angle, and configured to determine an estimate of an amplitude of the fundamental positive sequence component on the basis of the direct component; and an estimator configured to determine estimates of the estimated fundamental frequency and the estimated phase angle on the basis of the quadrature component.

A method for estimating a phase angle of a three-phase reference signal is disclosed, wherein the method comprises: calculating an estimated first state and an estimated second state of a model of an unbalanced three-phase system at s fundamental frequency of the reference signal on the basis of the reference signal and an estimated fundamental frequency, wherein the model comprises a first state representing a sum of a positive and a negative sequence component of the reference signal at a harmonic frequency, and a second state representing a difference between the positive sequence component and the negative sequence component; calculating a fundamental positive sequence component of the reference signal on the basis of the estimated first state and the estimated second state; calculating a direct component and a quadrature component in a rotating reference frame synchronous with an estimated phase angle on the basis of the fundamental positive sequence component and the estimated phase angle; determining an estimate of an amplitude of the fundamental positive sequence component on the basis of the direct component; and determining estimates of the estimated fundamental frequency and the estimated phase angle on the basis of the quadrature component.

### BRIEF DESCRIPTION OF THE DRAWINGS

In the following, the disclosure will be described in greater detail by means of exemplary embodiments with reference to the attached drawings, in which

FIG. 1 illustrates an exemplary phase-locked loop for estimating a phase angle and amplitude of the fundamental positive sequence component of a three-phase reference signal;

FIG. 2 illustrates an exemplary implementation of an unbalanced harmonics compensation mechanism;

FIGS. 3a to 3d illustrate a simulated transient response of the arrangement of FIGS. 1 and 2 to a change from balanced to unbalanced in a reference signal in accordance with an exemplary embodiment of the present disclosure;

FIGS. 4a to 4d illustrate a simulated transient response of the exemplary arrangement of FIGS. 1 and 2 to harmonic distortion added to the already unbalanced reference signal;

FIGS. 5a to 5d illustrate a simulated transient response of the exemplary arrangement of FIGS. 1 and 2 to a fundamental frequency step change; and

FIGS. 6a to 6d illustrate a simulated transient response of an exemplary SRF-PLL algorithm to a change from balanced to unbalanced in a reference signal.

### DETAILED DESCRIPTION

In accordance with an exemplary embodiment, an improved tolerance for harmonic distortion and unbalance can be achieved by using a method where a fundamental positive sequence component is first calculated from the reference signal, and the positive sequence component can be used to estimate the phase angle of the reference signal.

Calculation of the fundamental positive sequence component can be based on a description of a three-phase signal where the signal is described by a sum of positive and negative sequences in stationary-frame coordinates. In accordance with an exemplary embodiment, the fundamental positive sequence component can be extracted even under unbalanced conditions. The calculation of the fundamental positive sequence component can also include an explicit harmonic compensation mechanism (UHCM) which can deal with a possible unbalanced harmonic distortion present in the reference signal.

In accordance with an exemplary embodiment, as a result, the calculated fundamental positive sequence component can be largely free of harmonic distortion and unbalance.

In accordance with an exemplary embodiment, the fundamental positive sequence component can then be transformed into a synchronous reference frame and a quadrature component of the positive sequence component in the synchronous reference frame can be used to estimate the fundamental frequency and the phase angle of the reference signal. The estimated fundamental frequency, for example, can be used in the calculation of the fundamental positive sequence component.

An exemplary method is disclosed, which can provide clean estimates of the phase angle and the amplitude of the fundamental positive sequence component of a three-phase reference signal, even if the reference signal is subject to unbalance and harmonic distortion. The exemplary method can also be robust against angular frequency variations.

In accordance with an exemplary embodiment, knowledge about the phase angle and the amplitude of the fundamental positive sequence component of a three-phase reference signal can be used by some applications. For example, some applications can also use additional information, such as estimates of the angular frequency, and positive and negative sequences of the fundamental component of the reference signal. This can, for example, be the case in three-phase grid connected systems, such as power conditioning equipment, flexible ac transmission systems (FACTS), power line conditioners, regenerative drives, uninterruptible power supplies (UPS), grid connected inverters for alternative energy sources and other distributed generation and storage systems.

The present disclosure discloses a method for estimating a phase angle of a three-phase reference signal. The method can provide clean estimates of the phase angle and the amplitude of the fundamental positive sequence component of a three-phase reference signal, even when the reference signal is unbalanced and/or subject to harmonic distortion.

The disclosed method is robust against angular frequency variations, and can also provide estimates of the angular frequency, and both the positive and negative sequences of the fundamental component of the reference signal.

The disclosed method can extract a fundamental positive sequence component from the reference signal. The fundamental positive sequence component can then be transformed into a synchronous reference frame where the quadrature component of the fundamental positive sequence component can be controlled to zero in order to estimate the fundamental frequency and the phase angle of the reference signal.

Extraction of the fundamental positive sequence component can be performed on the basis of a model of an unbalanced three-phase signal. For example, a signal v_{αβ} can be seen as a sum of harmonics. Thus, a description of an unbalanced three-phase signal can involve a sum of positive and negative sequences in stationary-frame coordinates.

According to G. Escobar, S. Pettersson and C. N. M. Ho, “Phase-locked loop for grid synchronization under unbalanced operation and harmonic distortion,” in Proc. Industrial Electronics Conf. IECON11, Melbourne, November 2011, Vol. 1, pp. 623-628, the following model can describe a generator for a single unbalanced kth harmonic at a harmonic frequency kω₀:

\dot{v}_{αβ,k}=kω₀Jφ_{αβ,k},

\dot{φ}_{αβ,k}=kω₀Jv_{αβ,k}. (1)

The above model includes a first state v_{αβ,k} and a second state φ_{αβ,k}, where the states are represented in stationary αβ coordinates. Phase variables, such as phase voltages of a three-phase grid, can be transformed into αβ coordinates by using Clarke's transformation. In Equation (1), J is a transformation matrix defined as follows:

$$J = [ \begin{matrix}0 & - 1 \\ 1 & 0\end{matrix} ] . \qquad ( 2 )$$

The first state v_{αβ,k} represents a sum of a positive sequence component v_{αβ,k}^{p} and a negative sequence component v_{αβ,k}ⁿ of the reference signal at the harmonic frequency kω₀:

v_{αβ,k}=v_{αβ,k}^{p}+v_{αβ,k}ⁿ. (3)

In accordance with an exemplary embodiment, the first state v_{αβ,k} represents the kth unbalanced harmonic. The second state φ_{αβ,k} represents a difference between the positive sequence component and the negative sequence component:

φ_{αβ,k}=v_{αβ,k}^{p}−v_{αβ,k•}ⁿ. (4)

The model of Equation (1) forms an oscillator generating an unbalanced sinusoidal signal. In this disclosure, such an oscillator is referred to as an unbalanced harmonic oscillator (UHO).

The states of a kth harmonic in the reference signal can be estimated using, for example, the following estimator:

{circumflex over (\dot{v}_{αβ,k}=k\hat{ω}₀J\hat{φ}_{αβ,1}+γₖ\tilde{v}_{αβ,k},

{circumflex over (\dot{φ}_{αβ,k}=k\hat{ω}₀J\hat{v}_{αβ,k}, (5)

where \hat{v}_{αβ,k} and \hat{φ}_{αβ,k} are estimates of the first and the second state at the fundamental frequency, and \tilde{v}_{αβ,k} is a difference between the reference signal v_{αβ} and the unbalanced first harmonic, e.g., the first state \hat{v}_{αβ,k}. γₖ is a design parameter which introduces damping.

The model of Equation (1) and the estimator of Equation (5) can be used to extract the fundamental positive sequence component, e.g., the positive sequence component v_{αβ,1}^{p} of the first harmonic. However, in order to apply an estimator of Equation (5), an estimate \hat{ω}₀ of the fundamental frequency has to be known. Estimating the fundamental frequency will be discussed later in this disclosure.

On the basis of the reference signal v_{αβ} and the estimated fundamental frequency \hat{ω}₀, the disclosed method can calculate (e.g., via a processor) an estimated first state \hat{v}_{αβ,1} of the model and an estimated second state \hat{φ}_{αβ,1} of the model at the fundamental frequency of the reference signal v_{αβ}.

When values of the two estimated states are known, a fundamental positive sequence component \hat{v}_{αβ,1}^{p} of the reference signal v_{αβ} can be calculated on the basis of the estimated first state \hat{v}_{αβ,1} and the estimated second state \hat{φ}_{αβ,1}. A fundamental negative sequence component \hat{v}_{αβ,1}ⁿ of the reference signal can also be calculated on the basis of the estimated first state \hat{v}_{αβ,1} and the estimated second state \hat{φ}_{αβ,1} of the model of an unbalanced three-phase system.

In accordance with an exemplary embodiment, a synchronous reference frame approach can then be used with the fundamental positive sequence component \hat{v}_{αβ,1}^{p} as the new reference. On the basis of the fundamental positive sequence component \hat{v}_{αβ,1}^{p} and an estimated phase angle \hat{θ}₀, a direct component \hat{ν}_{d,1}^{p} and a quadrature component \hat{ν}_{q,1}^{p} in a rotating reference frame synchronous with the estimated phase angle can be calculated.

An estimate of an amplitude of the fundamental positive sequence component \hat{v}_{αβ,1}^{p} can be determined on the basis of the direct component \hat{ν}_{d,1}and estimates of the estimated fundamental frequency \hat{ω}₀ and the estimated phase angle \hat{θ}₀ can be determined on the basis of the quadrature component v_{q,1}^{p}.

The estimated phase angle \hat{θ}₀ can be determined by integrating the estimated fundamental frequency \hat{ω}₀. When the estimated phase angle \hat{θ}₀ follows the actual phase angle of the fundamental positive sequence component \hat{v}_{αβ,1}^{p} in synchrony, the magnitude of the quadrature component \hat{ν}_{q,1}^{p} is zero. According to an exemplary embodiment, the method can adjust the estimated fundamental frequency \hat{ω}₀, that is, the change rate of the estimated phase angle \hat{θ}₀, in order to minimize the magnitude of the quadrature component \hat{ν}_{q,1}^{p}.

In order to deal with harmonic distortion in the reference signal v_{αβ}, the disclosed method can also include extracting harmonic contents \hat{v}_{αβ,h} of the reference signal at least at one harmonic frequency other than a fundamental harmonic frequency of the reference signal. The harmonic distortion of the reference signal can be compensated for on the basis of the extracted harmonic content \hat{v}_{αβ,h}. In a manner similar to that in connection with the first harmonic, the extraction can be performed on the basis of the reference signal v_{αβ}, the estimated fundamental frequency \hat{ω}₀, and the model of an unbalanced three-phase system.

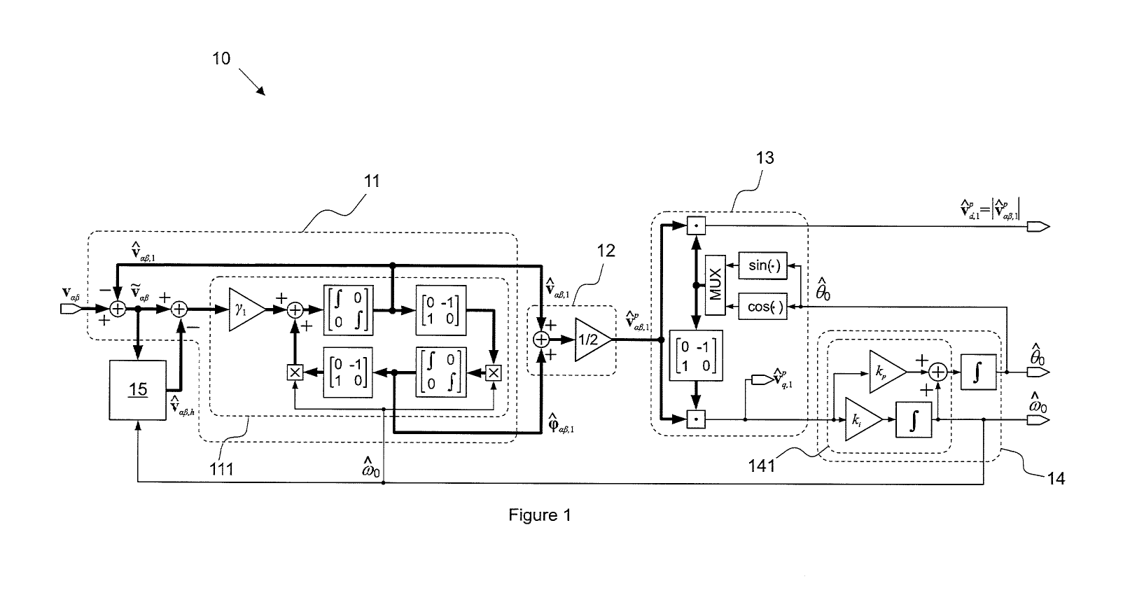

FIG. 1 illustrates an exemplary phase-locked loop 10 for estimating a phase angle and the amplitude of the fundamental positive sequence component of a three-phase reference signal. In FIG. 1, the phase-locked loop 10 includes an adaptive quadrature signal generator 11, a positive sequence generator 12, a reference frame transformation block 13, a controller 14, and an unbalanced harmonic compensation mechanism 15.

The adaptive quadrature signal generator 11 can act as a means for calculating an estimated first state \hat{v}_{αβ,1} of the model and an estimated second state \hat{φ}_{αβ,1} of the model at the fundamental frequency. In FIG. 1, the adaptive quadrature signal generator 11 calculates the estimated first state \hat{v}_{αβ,1} and the estimated second state \hat{φ}_{αβ,1} on the basis of the reference signal v_{αβ} and an estimated fundamental frequency \hat{ω}₀. Following Equation 5, the adaptive quadrature signal generator 11 includes an unbalanced harmonic oscillator 111 to which a difference \tilde{v}_{αβ} between the reference signal v_{αβ} and the estimated fundamental positive sequence component \hat{v}_{αβ,1}^{p} is fed.

The positive sequence generator 12 can act as a means for calculating the fundamental positive sequence component \hat{v}_{αβ,1}^{p}. The positive sequence generator 12 calculates the fundamental positive sequence component \hat{v}_{αβ,1}^{p} of the reference signal v_{αβ} on the basis of the estimated first state \hat{v}_{αβ,1} and the estimated second state \hat{φ}_{αβ,1}. In FIG. 1, the estimated states can be added together, and the resulting sum is divided by two.

The apparatus can also include a means for calculating a fundamental negative sequence component \hat{v}_{αβ,1}ⁿ of the reference signal on the basis of the estimated first state \hat{v}_{αβ,1} and the estimated second state \hat{φ}_{αβ,1} of the model of an unbalanced three-phase system. The fundamental negative sequence component \hat{v}_{αβ,1}ⁿ can, for example, be calculated by dividing a difference between the estimated first state \hat{v}_{αβ,1} and the estimated second state \hat{φ}_{αβ,1} by two.

The reference frame transformation block 13 can then calculate a direct component \hat{ν}_{d,1}^{p} and a quadrature component \hat{ν}_{q,1}^{p} in a rotating reference frame synchronous with the phase angle (dq coordinates). In FIG. 1, the reference frame transformation block 13 performs the transformation on the basis of the fundamental positive sequence component \hat{v}_{αβ,1}^{p} and an estimated phase angle \hat{0}₀. The reference frame transformation block 13 multiplies the fundamental positive sequence component \hat{v}_{αβ,1}^{p} by a normalized sinusoidal vector [cos(\hat{θ}₀); sin(\hat{θ}₀)]^{T} in order to transform the fundamental positive sequence component \hat{v}_{αβ,1}^{p} to the rotating reference frame. The controller 14 can act as a means for determining the estimated phase angle \hat{θ}₀. The controller 14 also determines the estimated fundamental frequency \hat{ω}₀ specified by the adaptive quadrature signal generator 11.

In FIG. 1, the controller 14 determines estimates of the estimated fundamental frequency \hat{ω}₀ and the estimated phase angle \hat{θ}₀ on the basis of the quadrature component \hat{ν}_{q,1}^{p}. When the normalized sinusoidal vector rotates at the same angular speed as the fundamental positive sequence component \hat{v}_{αβ,1}^{p}, the magnitude of the quadrature component \hat{ν}_{q,1}^{p} remains constant. A non-zero quadrature component magnitude indicates a phase shift between the sinusoidal vector and the fundamental positive sequence component \hat{v}_{αβ,1}^{p}. Thus, the controller 14 can try to minimize the magnitude of the quadrature component \hat{ν}_{q,1}^{p}. For example, this can be accomplished by adjusting the estimated fundamental frequency \hat{ω}₀, which is then integrated into the estimated phase angle \hat{θ}₀. Synchronization is achieved when magnitude of the quadrature component \hat{ν}_{q,1}^{p} is zeroed, e.g., when the estimated phase angle \hat{θ}₀ follows the phase angle of the fundamental positive sequence component \hat{v}_{αβ,1}^{p}.

When the magnitude of the quadrature component \hat{ν}_{q,1}^{p} is zero, the fundamental positive sequence component \hat{v}_{dq,1}^{p} in the rotating reference frame coordinates includes only the direct component \hat{ν}_{d,1}^{p}. Thus, the magnitude of the fundamental positive sequence component \hat{v}_{αβ,1}^{p} can be represented by the direct component \hat{ν}_{d,1}^{p}. In accordance with an exemplary embodiment, the reference frame transformation block 13 can also act as means for determining an estimate of an amplitude of the fundamental positive sequence component \hat{v}_{αβ,1}^{p} on the basis of the direct component \hat{ν}_{d,1}^{p}.

In FIG. 1, the controller 14 includes a PI controller 141 with control coefficients kₚ and kᵢ. The estimated fundamental frequency \hat{ω}₀ specified by the adaptive quadrature signal generator 11 is obtained directly from the integrating part of the PI controller 141 instead of the output of the PI controller 141. In FIG. 1, the output of the PI controller 141 can also be affected by the proportional part of the PI controller 141. Using this output can cause higher transients and distortions on all internal signals.

In order to deal with harmonic distortion, the exemplary phase-locked loop 10 of FIG. 1 can include an unbalanced harmonic compensation mechanism (UHCM) 15.

The unbalanced harmonic compensation mechanism 15 in FIG. 1 includes means for extracting harmonic contents \hat{v}_{αβ,h} of the reference signal at one or more harmonic frequencies other than a fundamental harmonic frequency of the reference signal, and means for compensating for the reference signal on the basis of the extracted harmonic content \hat{v}_{αβ,h}.

The harmonic contents \hat{v}_{αβ,h} can be extracted on the basis of the reference signal v_{αβ}, the fundamental frequency \hat{ω}₀, and the above model of the unbalanced three-phase system, e.g., a model that includes a first state representing a sum of a positive and a negative sequence component of the reference signal at the harmonic frequency in question, and a second state representing a difference between the positive sequence component and the negative sequence component of the reference signal at the harmonic frequency in question.

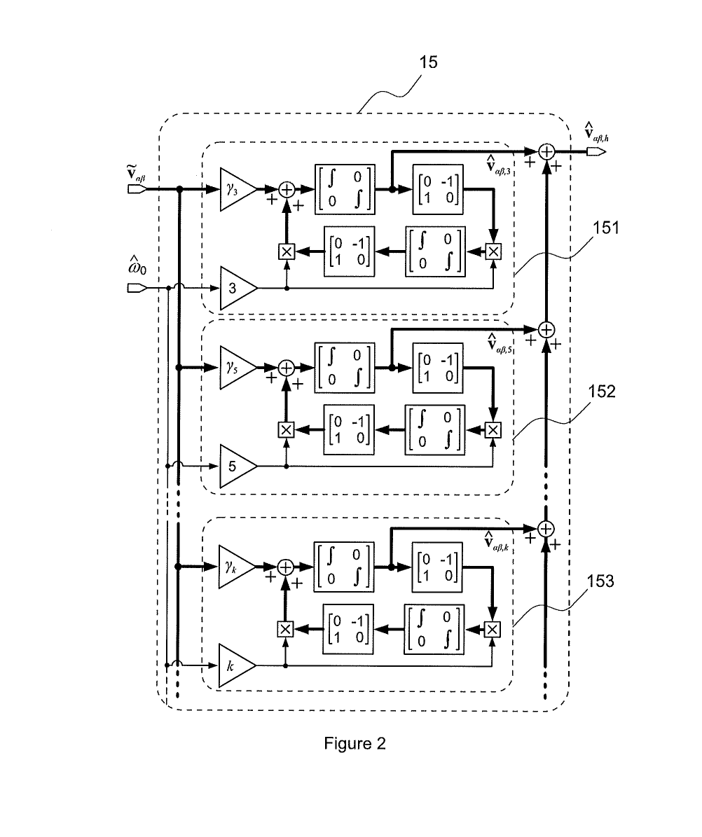

FIG. 2 illustrates an exemplary implementation of the UHCM. The UHCM 15 in FIG. 2 estimates selected harmonic components \hat{v}_{αβ,h} of the reference signal v_{αβ}. The UHCM 15 is composed of a bank of harmonic oscillators (UHO), each of them tuned at the harmonics under consideration. The design of the harmonic oscillators can, for example, follow the design of the estimator given in Equation 5. In FIG. 2, the topmost UHO 151 can be tuned for the 3rd harmonic and the next UHO 152 for the 5th harmonic. The bottommost UHO 153 illustrates a UHO tuned at an arbitrary harmonic k. The sum \hat{v}_{αβ, h}

of harmonic components extracted by the UHOs can be fed back to the arrangement of FIG. 1 in order to cancel their effect in the estimation of the fundamental positive sequence component \hat{v}_{αβ,1}^{p}.

In FIG. 1, the UHCM 15 appears as a plug-in block. In the case of low harmonic distortion, the UHCM 15 can be eliminated. For example, if the harmonic distortion does not exceed a set limit, the UHCM 15 can be disabled, and the control effort can, thus, be reduced.

An exemplary simulation of the implementation of FIGS. 1 and 2 will be discussed next. Values kₚ=10 and kᵢ=500 were selected for the controller 14, and a value of γ₁=400 was selected for the unbalanced harmonic oscillator (UHO) 111 of the adaptive quadrature signal generator 11. In accordance with an exemplary embodiment, it was assumed that the reference signal also contained 3rd and 5th harmonics, and, thus, the UHCM 15 contained UHOs 151 and 152 tuned to these harmonics. The gains of the UHOs 151 and 152 were set to γ₃=300 and γ₅=200. The reference signal had a nominal frequency of ω₀=314.16 rad/s (50 Hz), and an amplitude for its fundamental positive sequence of 100 V (the amplitude of the overall reference signal v_{αβ} was approximately 100 V). The simulation includes four steps.

First, in the time frame of t=0 to 1 s, the setup was simulated under balanced conditions. The reference signal was formed only by a fundamental positive sequence of 100 V of amplitude. The fundamental frequency was 314.16 rad/s (50 Hz), with a zero phase shift.

Second, in the time frame of t=1 s to 2 s, the setup was simulated under unbalanced conditions. The reference signal included positive and negative sequence components. The positive sequence had an amplitude of 100 Vat 314.16 rad/s (50 Hz) and a zero phase shift. For the negative sequence, an amplitude of 30 V and a phase shift of 1 rad were used.

Third, in the time frame of t=2 s to 3 s, the setup was simulated under unbalanced conditions with harmonic distortion. 3rd and 5th harmonics were added to the unbalanced signal of the second simulation step in order to create a periodic distortion. Both harmonics had also negative sequence components in order to have unbalance in the added harmonics as well.

Fourth, the setup was simulated with a frequency variation. A step change in the fundamental frequency of the reference signal was introduced at time t=3 s, changing from 314.16 rad/s (50 Hz) to 219.9 rad/s (35 Hz).

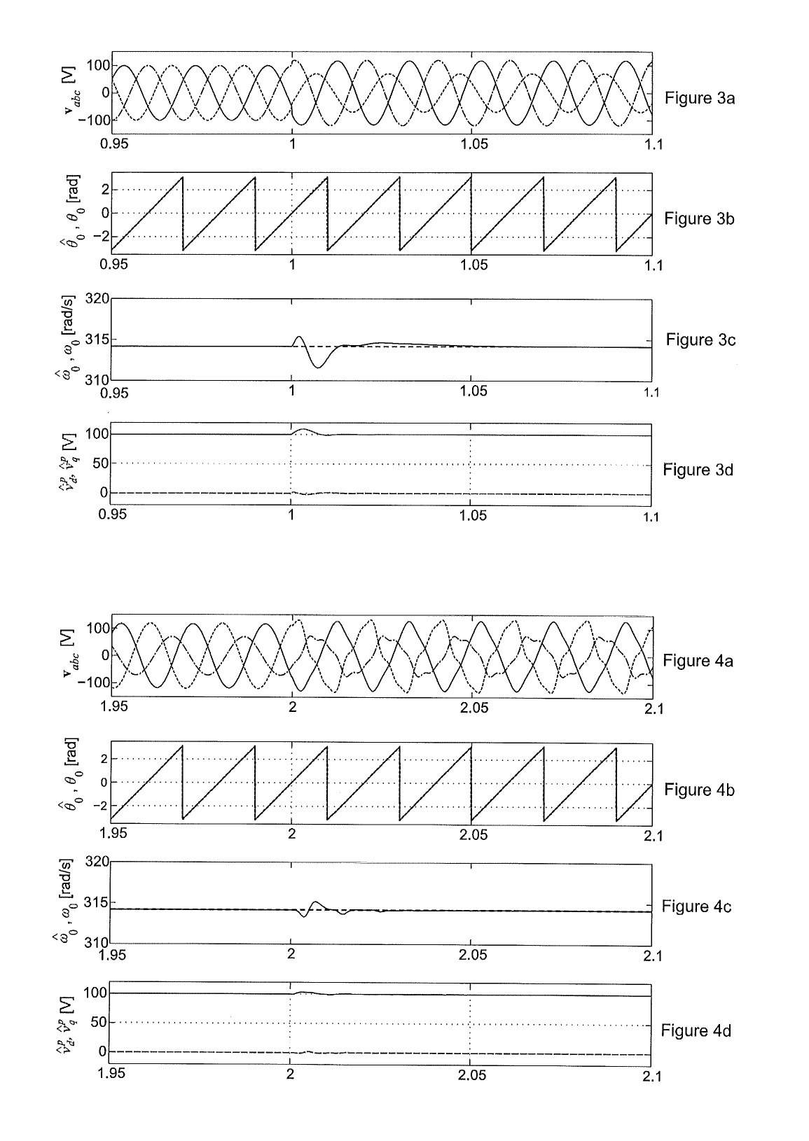

FIGS. 3a to 3d show a simulated transient response of the exemplary arrangement of FIGS. 1 and 2 to the change from balanced to unbalanced in a reference signal. In FIGS. 3a to 3d, 4a to 4d, 5a to 5d, and 6a to 6d, the reference signal is represented by three phase voltages v_{abc}. At time t=1 s, the reference signal v_{abc}, represented by three phase voltages in FIG. 3a, is changed from balanced to unbalanced. After short transients, the estimated signals in FIGS. 3b to 3d returned to their desired values. In FIG. 3b, an estimated phase angle \hat{θ}₀ (in solid line) followed an actual phase angle θ₀ (in dashed line) after almost an imperceptible transient. In FIG. 3c, an estimated frequency \hat{ω}₀ (solid line) closely followed a reference ω₀ fixed at 316.14 rad/s (dotted line) after a small transient. In FIG. 3d, the estimated dq components \hat{ν}_{d,1}^{p} (solid line) and \hat{ν}_{q,1}^{p} (dashed line) of the positive-sequence of the fundamental component maintained constant values, e.g., \hat{ν}_{d}^{p}=100 V and \hat{ν}_{q}^{p}=0 V, after an almost imperceptible variation.

FIGS. 4a to 4d show the simulated transient response of the exemplary arrangement of FIGS. 1 and 2 to the harmonic distortion added to the already unbalanced reference signal. At time t=2 s, the harmonic distortion was added to the reference signal v_{abc} in FIG. 4a. After short transients, the estimated signals in FIGS. 4b to 4d returned to their desired values.

In FIG. 4c, the estimated frequency \hat{ω}₀ (solid line) closely followed its reference ω₀ fixed at 316.14 rad/s (dotted line) after a small transient and without further fluctuations. The estimated dq components \hat{ν}_{d,1}^{p} (solid line) and \hat{ν}_{q,1}^{p} (dashed line) in FIG. 4d, as well as the estimated phase angle \hat{θ}₀ in FIG. 4b, reached the corresponding references with an almost imperceptible transient.

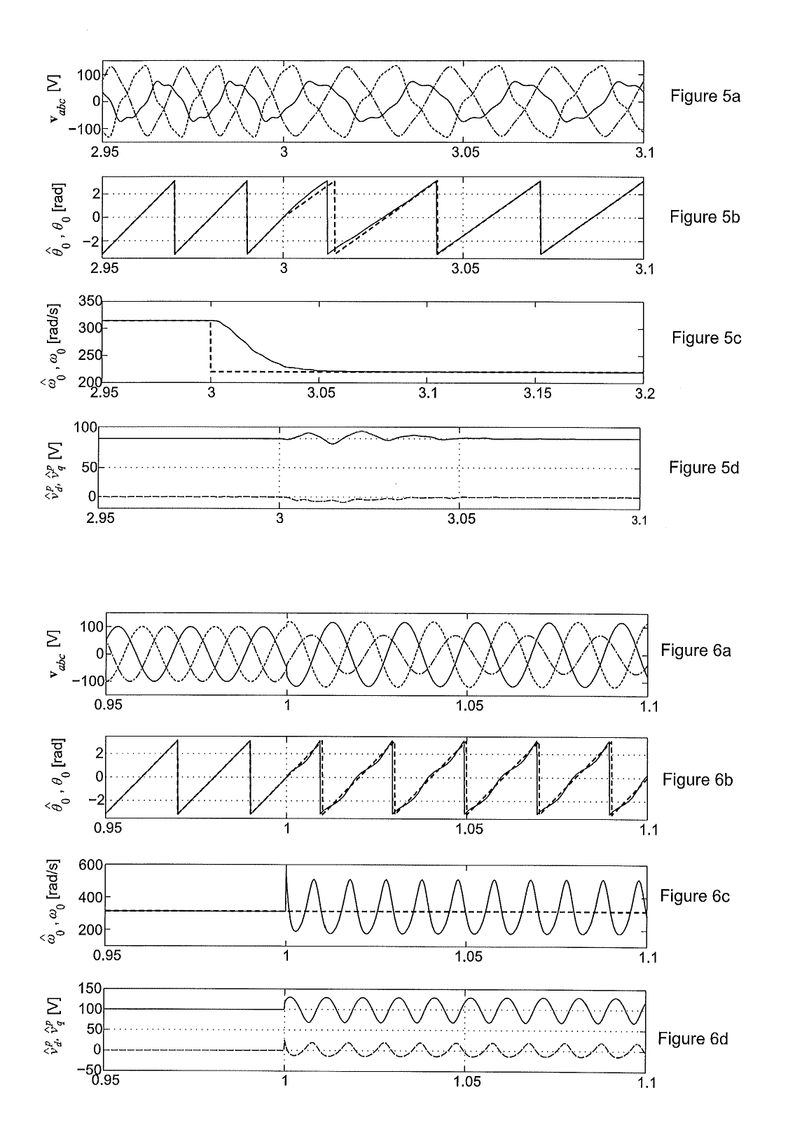

FIGS. 5a to 5d show a simulated transient response of the exemplary arrangement of FIGS. 1 and 2 to the step change in the angular frequency of the reference signal changing from ω₀=314.16 rad/s (50 Hz) to ω₀=219.9 rad/s (35 Hz). After a short transient, the estimated phase angle \hat{θ}₀ (in solid line) in FIG. 5c followed the actual phase angle θ₀ (in dashed line). The estimated fundamental frequency \hat{ω}₀ in FIG. 5c, starting at a reference of 314.16 rad/s (50 Hz), reached its new reference fixed at 219.9 rad/s (35 Hz) in a relatively short time. In FIG. 5d, the estimated dq components \hat{ν}_{d,1}^{p} (solid line) and \hat{ν}_{q,1}^{p} (dashed line) of the positive-sequence of the reference maintained their constant values after a short transient.

For comparison, a SRF-PLL scheme as disclosed in V. Kaura and V. Blasco, “Operation of a phase locked loop system under distorted utility conditions,” IEEE Trans. on Ind. Appl., Vol. 33, Issue 1, pp. 58-63, January/February 1997 was also simulated. The SRF-PLL was tuned to avoid excess of ripple, while still allowing for an acceptable dynamical response. FIGS. 6a to 6d show the transient response obtained with the SRF-PLL algorithm when the reference signal v_{abc} in FIG. 6a changed from a balanced to an unbalanced operation condition at time t=1 s. FIG. 6d shows a persistent fluctuation in the estimated dq components \hat{ν}_{d,1}^{p} (solid line) and \hat{ν}_{q,1}^{p} (dashed line) of the positive-sequence of the reference. In accordance with an exemplary embodiment, the fluctuation in the estimated dq components caused a fluctuation in the estimated fundamental frequency \hat{ω}₀ in FIG. 6c, which propagated to the estimated phase angle \hat{Θ}₀ in FIG. 6b.

FIGS. 6a to 6d illustrate that the SRF-PLL scheme lacked means for dealing with the unbalanced operation. Similar results were obtained when harmonic distortion was added on top of the unbalance.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A phase-locked loop for estimating a phase angle of a three-phase reference signal, wherein the phase-locked loop comprises:
an adaptive quadrature signal generator configured to calculate an estimated first state and an estimated second state of a model of an unbalanced three-phase system at a fundamental frequency of the reference signal on a basis of the reference signal and an estimated fundamental frequency, wherein the model includes a first state representing a sum of a positive and a negative sequence component of the reference signal at a harmonic frequency, and a second state representing a difference between the positive sequence component and the negative sequence component;
a positive sequence generator configured to calculate a fundamental positive sequence component of the reference signal on a basis of the estimated first state and the estimated second state;
a reference frame transformation block configured to calculate a direct component and a quadrature component in a rotating reference frame synchronous with an estimated phase angle on a basis of the fundamental positive sequence component and the estimated phase angle, and configured to determine an estimate of an amplitude of the fundamental positive sequence component on the basis of the direct component; and
an estimator configured to determine estimates of the estimated fundamental frequency and the estimated phase angle on the basis of the quadrature component.

2. A phase-locked loop according to claim 1, comprising:
an unbalanced harmonic compensation mechanism configured to extract harmonic contents of the reference signal at least at one harmonic frequency other than a fundamental harmonic frequency of the reference signal on the basis of the reference signal, the estimated fundamental frequency, and the model of an unbalanced three-phase system, and configured to compensate for the reference signal on the basis of the extracted harmonic content.

3. A phase-locked loop according to claim 1, comprising:
means for calculating a fundamental negative sequence component of the reference signal on the basis of the estimated first state and the estimated second state of the model of an unbalanced three-phase system.

4. A phase-locked loop according to claim 1, wherein the estimator configured to determine estimates of the estimated fundamental frequency and the estimated phase angle includes a controller configured to minimize the magnitude of the quadrature component.

5. A phase-locked loop according to claim 4, wherein the controller includes a PI controller and the estimated fundamental frequency is obtained directly from an integrating part of the PI controller.

6. A phase-locked loop according to claim 2, wherein the unbalanced harmonic compensation mechanism is configured to be disabled if harmonic distortion does not exceed a set limit.

7. A method for estimating a phase angle of a three-phase reference signal, wherein the method comprises:
calculating an estimated first state and an estimated second state of a model of an unbalanced three-phase system at s fundamental frequency of the reference signal on the basis of the reference signal and an estimated fundamental frequency, wherein the model comprises a first state representing a sum of a positive and a negative sequence component of the reference signal at a harmonic frequency, and a second state representing a difference between the positive sequence component and the negative sequence component;
calculating a fundamental positive sequence component of the reference signal on the basis of the estimated first state and the estimated second state;
calculating a direct component and a quadrature component in a rotating reference frame synchronous with an estimated phase angle on the basis of the fundamental positive sequence component and the estimated phase angle;
determining an estimate of an amplitude of the fundamental positive sequence component on the basis of the direct component; and
determining estimates of the estimated fundamental frequency and the estimated phase angle on the basis of the quadrature component.

8. A method according to claim 7, comprising:
extracting harmonic contents of the reference signal at least at one harmonic frequency other than a fundamental harmonic frequency of the reference signal on the basis of the reference signal, the estimated fundamental frequency, and the model of an unbalanced three-phase system, and
compensating for the reference signal on a basis of the extracted harmonic content.

9. A method according to claim 7, comprising:
calculating a fundamental negative sequence component of the reference signal on the basis of the estimated first state and the estimated second state of the model of an unbalanced three-phase system.

10. A method according to claim 7, comprising:
minimizing the magnitude of the quadrature component with a controller.

11. A method according to claim 10, wherein the controller comprises a PI controller and the estimated fundamental frequency is obtained directly from an integrating part of the PI controller.

12. A method according to claim 8, comprising:
disabling the steps of extracting harmonic contents of the reference signal at least at one harmonic frequency other than a fundamental harmonic frequency of the reference signal on the basis of the reference signal, and compensating for the reference signal on the basis of the extracted harmonic content, if harmonic distortion does not exceed a set limit.
